(19) United States
(12) Patent Application Publication
(10) Pub. No.: US 2025/0250458 A1
(43) Pub. Date: Aug. 7, 2025

(54) ENCAPSULATION EPOXY RESIN COMPOSITION AND ELECTRONIC DEVICE

(71) Applicant: Panasonic Intellectual Property Management Co., Ltd., Osaka (JP)

(72) Inventors: Yasuaki MAEDA, Mie (JP); Kazuto OGAWA, Mie (JP); Hiroyuki FUJIWARA, Mie (JP)

(21) Appl. No.: 18/849,738

(22) PCT Filed: Mar. 22, 2023
(86) PCT No.: PCT/JP2023/011275

§ 371 Date: Sep. 23, 2024

(30) Foreign Application Priority Data
Mar. 25, 2022 (JP) 2022-050783

(51) Int. Cl. C09D 163/00; C08G 59/62; C08G 59/68; C09D 7/40; C09D 7/61; H01L 23/29

(52) U.S. Cl. CPC C09D 163/00; C08G 59/621; C08G 59/686; C09D 7/61; C09D 7/68; C09D 7/69; H01L 23/295

(57) ABSTRACT

An encapsulation epoxy resin composition contains an epoxy resin (A), a curing agent (B), a curing accelerator (C), and an inorganic filler (D). The curing accelerator (C) contains an amidine silicate (C1) expressed by the following formula (1):

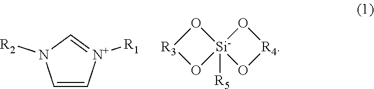

### TECHNICAL FIELD

The present disclosure generally relates to an encapsulation epoxy resin composition and an electronic device. More particularly, the present disclosure relates to an encapsulation epoxy resin composition and an electronic device including an encapsulation portion formed out of the encapsulation epoxy resin composition.

### BACKGROUND ART

Patent Literature 1 discloses an encapsulation epoxy resin composition including an epoxy resin (A), a phenolic-resin-based curing agent (B), an inorganic filler (C), and a curing accelerator (D). According to Patent Literature 1, the curing accelerator (D) has a mean particle size equal to or less than 10 μm and may contain at least one compound selected from the group consisting of a phosphobetaine compound, an adduct of a phosphine compound and a quinone compound, and an adduct of a phosphonium compound and a silane compound (refer to paragraph 0032 of Patent Literature 1).

### CITATION LIST

### Patent Literature

Patent Literature 1: WO 2012/102336 A1

### SUMMARY OF INVENTION

An object of the present disclosure is to provide an encapsulation epoxy resin composition which has a high degree of storage stability, and which may increase a curing rate at the time of curing and an electronic device.

An encapsulation epoxy resin composition according to an aspect of the present disclosure contains an epoxy resin (A), a curing agent (B), a curing accelerator (C), and an inorganic filler (D). The curing accelerator (C) contains an amidine silicate (C1) expressed by the following formula (1):

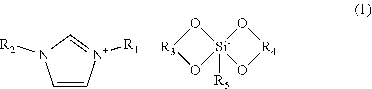

In the formula (1), R₁ and R₂ are each independently either a hydrogen atom or an aliphatic hydrocarbon group having one to five carbon atoms, R₃ and R₄ are each independently either a phenylene group or a naphthylene group, and R₅ is at least one group selected from the group consisting of a phenyl group, a functional group expressed by the following formula (2), and a functional group expressed by the following formula (3):

—CₙH₂ₙ—X (2)

In the formula (2), n is equal to or greater than 3 and equal to or less than 8, and X is at least one functional group selected from the group consisting of —SH, —NH, —NH-Ph, -Ph-CH═CH₂, —NH—C₂H₄—NH₂, —N═C═O, a glycidyl ether group, and a group expressed by the following formula (3),

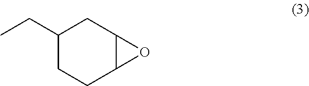

An electronic device according to another aspect of the present disclosure includes a semiconductor element and an encapsulation portion encapsulating the semiconductor element. The encapsulation portion is a cured product of the encapsulation epoxy resin composition described above.

### BRIEF DESCRIPTION OF DRAWINGS

FIG. 1 is a schematic cross-sectional view illustrating an electronic device according to an exemplary embodiment of the present disclosure.

### Description of Embodiments

### 1. Overview

First, it will be described how the present inventors conceived the concept of the present disclosure.

As described above, Patent Literature 1 (WO 2012/102336 A1) discloses an encapsulation epoxy resin composition including an epoxy resin (A), a phenolic-resin-based curing agent (B), an inorganic filler (C), and a curing accelerator (D).

The present inventors discovered, as a result of our unique research, that preparing an encapsulation resin composition by compounding an epoxy resin, a curing agent, and a curing accelerator as in Patent Literature 1 sometimes caused a decrease in the storage stability of the resin composition. In addition, the present inventors also discovered that attempting to increase the storage stability of the resin composition sometimes caused a decrease in curing rate at the time of curing. Thus, to overcome such a problem, the present inventors carried out extensive research to eventually conceive the concept of an encapsulation epoxy resin composition according to the present disclosure.

An encapsulation epoxy resin composition according to an exemplary embodiment contains an epoxy resin (A), a curing agent (B), a curing accelerator (C), and an inorganic filler (D). The curing accelerator (C) contains an amidine silicate (C1) expressed by the following formula (1):

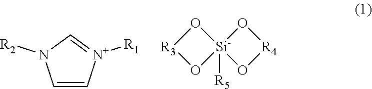

The encapsulation epoxy resin composition is curable through the reaction between the epoxy resin (A) and the curing agent (B). Adding the curing accelerator (C) to the encapsulation epoxy resin composition allows the reaction to proceed even more efficiently. The inorganic filler (D) enables adjusting the physical properties, such as the heat resistance, thermal conductivity, and coefficient of linear expansion, of an encapsulation portion formed out of the encapsulation epoxy resin composition.

Meanwhile, if an encapsulation epoxy resin composition prepared were left, then reaction would proceed even at room temperature, for example, due to the increased degree of reactivity of the encapsulation epoxy resin composition as described above, thus making it difficult to store the encapsulation epoxy resin composition as prepared. That is to say, in that case, it would be difficult to maintain the high degree of storage stability of the encapsulation epoxy resin composition. In contrast, in the encapsulation epoxy resin composition according to this embodiment, the curing accelerator (C) contains the amidine silicate (C1) expressed by the formula (1), thus enabling increasing the degree of storage stability of the encapsulation epoxy resin composition without causing a decrease in the curability of the encapsulation epoxy resin composition while heating and curing the encapsulation epoxy resin composition.

The reason why the above-described configuration according to this embodiment achieves the high degree of storage stability and the high curing rate at the time of curing is not completely clear but is probably as follows. The amidine silicate (C1) contained in the curing accelerator (C) is a curing accelerator consisting essentially of an amidine cation and a silicate anion. The amidine cation has a relatively high degree of basicity and may have a high degree of activity, while the silicate anion has a skeleton derived from either dihydroxy naphthalene or catechol, and therefore, tends to have a high melting point. That is why the amidine silicate (C1) tends to keep its activity low enough under a temperature condition such as room temperature but tends to increase its activity increasingly significantly as the temperature rises. The amidine silicate (C1) may have its activity increased particularly significantly when heated to a temperature around its melting point. Thus, the amidine silicate (C1) would make it easier to increase the degree of storage stability of the encapsulation epoxy resin composition and would be active enough to increase the curing rate of the encapsulation epoxy resin composition sufficiently while the encapsulation epoxy resin composition is being heated and cured.

As can be seen, this embodiment enables providing an encapsulation epoxy resin composition having a high degree of storage stability and having the ability to increase the curing rate at the time of curing. Thus, the encapsulation epoxy resin composition according to this embodiment may be used suitably to encapsulate an electronic component such as a semiconductor element in an electronic device.

### 2. Details

Next, an encapsulation epoxy resin composition and electronic device 1 according to this embodiment will be described in further detail. Note that the exemplary embodiment to be described below is only an exemplary one of various embodiments of the present disclosure and should not be construed as limiting. Rather, the exemplary embodiment may be readily modified in various manners depending on a design choice or any other factor without departing from the scope of the present disclosure.

### <Encapsulation Epoxy Resin Composition>

First, components that may be contained in the encapsulation epoxy resin composition will be described in detail. The encapsulation epoxy resin composition according to this embodiment contains an epoxy resin (A), a curing agent (B), a curing accelerator (C), and an inorganic filler (D) as described above.

### [Epoxy Resin]

The epoxy resin (A) is a thermosetting component. In this embodiment, the epoxy resin (A) may be caused to react and cured by heating the epoxy resin (A) and the curing agent (B) in the encapsulation epoxy resin composition. The epoxy resin (A) may impart heat resistance to a cured product of the encapsulation epoxy resin composition.

The epoxy resin (A) contains at least one component selected from the group consisting of, for example, a glycidyl ether epoxy resin, a glycidyl amine epoxy resin, a glycidyl ester epoxy resin, and an olefin oxidation (alicyclic) epoxy resin. More specifically, the epoxy resin includes one or more components selected from the group consisting of, for example, alkyl-phenol-novolac epoxy resins such as a phenol-novolac epoxy resin and a cresol-novolac epoxy resin; naphthol-novolac epoxy resins; phenol-aralkyl epoxy resins having a phenylene skeleton or a biphenylene skeleton, for example; biphenyl-aralkyl epoxy resins; naphthol-aralkyl epoxy resins having a phenylene skeleton or a biphenylene skeleton, for example; polyfunctional epoxy resins such as triphenol-methane epoxy resins and alkyl-modified triphenol-methane epoxy resins; triphenyl-methane epoxy resins; tetrakisphenol ethane epoxy resins; dicyclopentadiene epoxy resins; stilbene epoxy resins; bisphenol epoxy resins such as bisphenol A epoxy resins and bisphenol F epoxy resins; biphenyl epoxy resins; naphthalene epoxy resins; alicyclic epoxy resins; bromine-containing epoxy resins such as bisphenol A bromine-containing epoxy resins; glycidyl-amine epoxy resins produced by reaction between epichlorohydrin and polyamines such as diaminodiphenylmethane and isocyanuric acid; and glycidyl-ester epoxy resins produced by reaction between polybasic acids such as phthalic acid and dimer acid and epichlorohydrin.

Note that these are only exemplary components that may be contained in the epoxy resin (A) of the encapsulation epoxy resin composition and should not be construed as limiting. Alternatively, the epoxy resin (A) of the encapsulation epoxy resin composition may also contain any other resin with an epoxy group. The resin with the epoxy group may be either a monomer or a prepolymer, whichever is appropriate.

### [Curing Agent]

The curing agent (B) is a compound which may react with the epoxy resin (A) in the encapsulation epoxy resin composition as described above.

The curing agent (B) may contain a phenolic compound, for example. Adding a phenolic compound to the curing agent (B) allows the epoxy resin (A) and the curing agent (B) to produce thermosetting reaction.

The phenolic compound preferably includes at least one component selected from the group consisting of, for example: novolac resins such as phenol-novolac resins, cresol-novolac resins, and naphthol-novolac resins; phenol-aralkyl resins having either a phenylene skeleton or a biphenylene skeleton; aralkyl resins such as naphthol aralkyl resins having either a phenylene skeleton or a biphenylene skeleton; polyfunctional phenolic resins such as triphenolmethane resins; dicyclopentadiene phenolic resins such as dicyclopentadiene phenol-novolac resins and dicyclopentadiene naphthol-novolac resins; terpene-modified phenolic resins; bisphenol resins such as bisphenol A and bisphenol F resins; and triazine-modified novolac resins.

Note that the curing agent (B) does not have to be a phenolic compound as long as the curing agent (B) may produce thermosetting reaction with the epoxy resin (A). For example, the curing agent (B) may contain at least one component selected from the group consisting of a phenolic compound, an acid anhydride, an imidazole compound, and an amine compound.

The equivalent of the epoxy resin (A) per equivalent of the curing agent (B) is preferably equal to or greater than 0.6 eq. and equal to or less than 10 eq. Setting the equivalent of the epoxy resin (A) at a value equal to or less than 10 eq. allows the encapsulation epoxy resin composition to have good curability and also allows a cured product thereof to have sufficient heat resistance and mechanical strength. Setting the equivalent of the epoxy resin (A) at a value equal to or greater than 0.6 eq. allows the cured product to have high moisture resistance. The equivalent of the epoxy resin (A) per equivalent of the curing agent (B) is more preferably equal to or greater than 0.8 eq. and equal to or less than 5 eq.

### [Curing Accelerator]

The curing accelerator (C) is a compound which may accelerate the curing reaction between the epoxy resin (A) and the curing agent (B) in the encapsulation epoxy resin composition. In this embodiment, the curing accelerator (C) contains the amidine silicate (C1) expressed by the following formula (1):

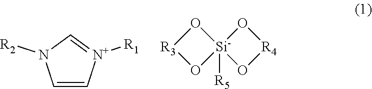

### (Amidine Silicate)

The amidine silicate (C1) has a cation part having an amidine skeleton and an anion part having a silicate skeleton. In this embodiment, as expressed by the formula (1), the cation part has an imidazolium skeleton, and the anion part has a silicate anion. The amidine silicate (C1) may contribute to increasing the storage stability of the encapsulation epoxy resin composition and increasing the curing rate at the time of curing. Moreover, the amidine silicate (C1) has excellent compatibility with the epoxy resin (A) and the curing agent (B). Therefore, even when the encapsulation epoxy resin composition is prepared, the amidine silicate (C1) does not aggregate easily, which may increase the degree of dispersibility of the encapsulation epoxy resin composition in a molten state.

The amidine silicate (C1) has a relatively high melting point. This makes it easier to prepare the encapsulation epoxy resin composition at an ordinary temperature (such as room temperature of about 25° C.) in solid form and thereby increase the degree of storage stability of the encapsulation epoxy resin composition. If the cation part has a high degree of basicity, then the activity tends to be high. In contrast, the amidine silicate (C1) according to this embodiment has a high melting point and is in solid form at an ordinary temperature, thus reducing the chances of causing an increase in the degree of activity while the encapsulation epoxy resin composition is stored and not causing a decrease in storage stability. In addition, when the encapsulation epoxy resin composition is heated and cured, the amidine silicate (C1) is activated enough to cure the encapsulation epoxy resin composition in a relatively short time. The melting point of the amidine silicate (C1) is preferably equal to or higher than 160° C., more preferably equal to or higher than 180° C., and even more preferably equal to or higher than 200° C. The upper limit of the melting point of the amidine silicate (C1) may be, without limitation, equal to or lower than 300° C., for example.

In the formula (1) expressing the amidine silicate (C1), R₁ and R₂ are each independently either a hydrogen atom or an aliphatic hydrocarbon group having one to five carbon atoms. R₁ and R₂ are preferably each independently an aliphatic hydrocarbon group having one to twenty carbon atoms, and more preferably each independently an aliphatic hydrocarbon group having one to ten carbon atoms. This allows the cation part to maintain moderate basicity without increasing its basicity too much, thus reducing the chances of causing a decrease in the flowability of the encapsulation epoxy resin composition in the molten state. Optionally, the amidine silicate (C1) may contain multiple types of compounds expressed by the formula (1). For example, the amidine silicate (C1) may contain multiple compounds which are different from each other in only R₁ in the formula (1), or multiple compounds which are different from each other in only R₂ in the formula (1), or multiple compounds which are different from each other in both R₁ and R₂.

In the formula (1) expressing the amidine silicate (C1), R₃ and R₄ are each independently either a phenylene group or a naphthylene group, and R₅ is at least one group selected from the group consisting of a phenyl group and a group expressed by the following formula (2). Optionally, the amidine silicate (C1) may contain multiple types of compounds expressed by the formula (1). For example, the amidine silicate (C1) may contain multiple compounds which are different from each other in only R₃ in the formula (1), or multiple compounds which are different from each other in only R₄ in the formula (1), or multiple compounds which are different from in both R₃ and R₄.

—CₙH₂ₙ—X (2)

In the formula (2) expressing the amidine silicate (C1), X is at least one functional group selected from the group consisting of —SH, —NH, —NH-Ph, —Ph-CH═CH₂, —NH—C₂H₄—NH₂, —N═C═O, a glycidyl ether group, and a group expressed by the following formula (3):

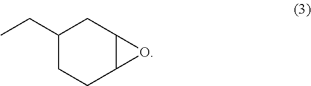

In the formula (1), R₅ is a side chain group having an ethylene chain bonded to a silicon atom. If X in the formula (2) is at least one group selected from the group consisting of —SH, —NH, -NH-Ph, —Ph-CH =CH₂, —NH—C₂H₄—NH₂, —N═C═O, a glycidyl ether group, and the group expressed by formula (3), then an amidine silicate (C1) with a high melting point may be obtained easily. This is because selecting at least one of these groups as X would reduce the chances of reducing an increase in the melting point of the amidine silicate (C1) due to the presence of a phenylene group or naphthylene group bonded to a silicon atom via an oxygen atom and would reduce the chances of affecting the crystallinity. As used herein, “-Ph” in “-NH-Ph” refers to a phenyl group, and “-Ph-” in “-Ph-CH═CH_{2”} refers to a phenylene group.

In the formula (1) expressing the amidine silicate (C1), R₁ and R₂ are preferably each independently a hydrocarbon group having one or two carbon atoms, and R₅ is preferably a phenyl group or C₃H₆SH. This enables further increasing the storage stability of the encapsulation epoxy resin composition and achieving an even higher degree of curability while the encapsulation epoxy resin composition is being cured.

The amidine silicate (C1) preferably includes at least one compound selected from the group consisting of the compounds expressed by the following formulae (11), (12), and (13). This enables further increasing the storage stability of the encapsulation epoxy resin composition and achieving an even higher degree of curability while the encapsulation epoxy resin composition is being cured.

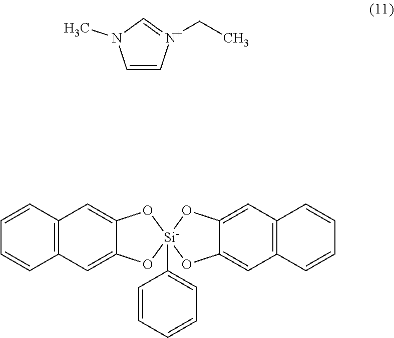

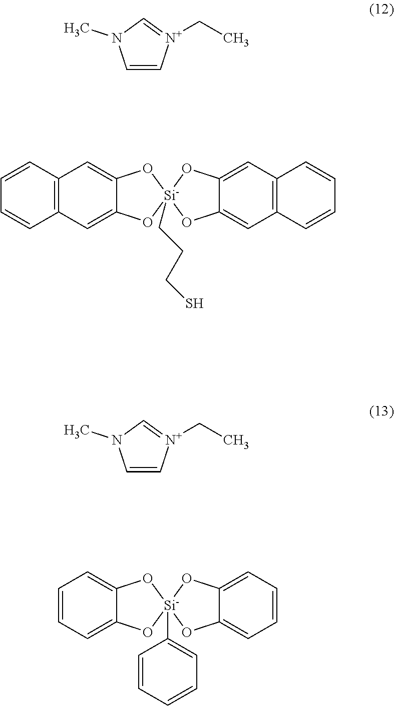

Note that the compounds expressed by these formulae (11) to (13) may be synthesized by the method disclosed in JP 6917707 B2.

In the encapsulation epoxy resin composition, the proportion of the curing accelerator (C) to 100 parts by mass in total of the epoxy resin (A) and the curing agent (B) is preferably equal to or greater than 1 part by mass and equal to or less than 35 parts by mass. Setting the proportion of the curing accelerator (C) at a value equal to or greater than 1 part by mass makes it even easier to increase the curing rate of the encapsulation epoxy resin composition at the time of curing. Setting the proportion of the curing accelerator (C) at a value equal to or less than 35 parts by mass makes it easier for the encapsulation epoxy resin composition to maintain an even higher degree of storage stability. The proportion of the curing accelerator (C) to 100 parts by mass in total of the epoxy resin (A) and the curing agent (B) is more preferably equal to or greater than 3 parts by mass and equal to or less than 25 parts by mass and even more preferably equal to or greater than 3 parts by mass and equal to or less than 20 parts by mass.

The proportion of the amidine silicate (C1) to 100 parts by mass in total of the epoxy resin (A) and the curing agent (B) is preferably equal to or greater than 1 part by mass and equal to or less than 35 parts by mass. Setting the proportion of the amidine silicate (C1) at a value equal to or greater than 1 part by mass makes it even easier to increase the curing rate of the encapsulation epoxy resin composition at the time of curing. Setting the proportion of the amidine silicate (C1) at a value equal to or less than 35 parts by mass makes it easier for the encapsulation epoxy resin composition to maintain an even higher degree of storage stability. The proportion of the amidine silicate (C1) to 100 parts by mass in total of the epoxy resin (A) and the curing agent (B) is more preferably equal to or greater than 3 parts by mass and equal to or less than 25 parts by mass and even more preferably equal to or greater than 3 parts by mass and equal to or less than 20 parts by mass.

### [Inorganic Filler (D)]

The encapsulation epoxy resin composition contains an inorganic filler (D). The inorganic filler (D) may improve the heat resistance and thermal conductivity of the encapsulation portion 4. In addition, the inorganic filler (B) may decrease the coefficient of linear expansion of the encapsulation portion 4 as well.

The inorganic filler (D) preferably has a mean particle size equal to or greater than 0.5 μm and equal to or less than 15 μm. This makes it easier to maintain sufficient flowability for the encapsulation epoxy resin composition without causing a decrease in the flowability. Note that the mean particle size of the inorganic filler (D) according to the present disclosure refers to a volume-based median diameter (D50). The median diameter (D50) may be calculated based on a particle size distribution measured by the laser diffraction scattering method. The particle size distribution may be measured using a laser diffraction particle size analyzer, for example. As the laser diffraction particle size analyzer, “MT3300EX2” manufactured by MicrotracBEL Corporation may be used, for example.

The inorganic filler (D) preferably includes inorganic particles each having a particle size equal to or less than 0.1 μm. The proportion of the inorganic particles to 100 parts by weight of the inorganic filler (D) is preferably equal to or greater than 0.1 parts by weight and equal to or less than 30 parts by weight. This makes it easier to maintain an even higher degree of flowability for the encapsulation epoxy resin composition in the molten state. The lower limit of the particle size of inorganic particles is not limited to any particular value. According to the present disclosure, the proportion of such inorganic particles each having a particle size equal to or less than 0.1 μm may be checked by measuring a frequency distribution with a particle size equal to or less than 0.1 μm using a laser diffraction particle size analyzer, which may be the same as the particle size analyzer mentioned above.

As the inorganic filler (D), any appropriate material may be used without limitation as long as an object of the present disclosure is achievable. For example, the inorganic filler (D) may contain at least one component selected from the group consisting of fused silicas such as a fused spherical silica, crystal silica, alumina, aluminum nitride, and silicon nitride.

In the encapsulation epoxy resin composition, the proportion of the inorganic filler (D) to the total of the epoxy resin (A), the curing agent (B), the curing accelerator (C), and the inorganic filler (D) is preferably equal to or greater than 60% by mass and equal to or less than 93% by mass. Setting the proportion of the inorganic filler (D) at a value equal to or greater than 60% by mass makes it even easier to maintain sufficient flowability for the encapsulation epoxy resin composition in the molten state. Setting the proportion of the inorganic filler (D) at a value equal to or less than 93% by mass makes it easier to ensure sufficient fillability for the encapsulation epoxy resin composition. The proportion of the inorganic filler (D) to the total of the epoxy resin (A), the curing agent (B), the curing accelerator (C), and the inorganic filler (D) is more preferably equal to or greater than 60% by mass and equal to or less than 90% by mass and even more preferably equal to or greater than 65% by mass and equal to or less than 90% by mass.

### [Other Components]

The encapsulation epoxy resin composition may further contain any appropriate compounds, resins, additives, and other components besides the essential components described above. Examples of such additives include appropriate antifoaming agents, surface conditioning agents, coupling agents, fluxes, viscosity modifiers, leveling agents, low stress agents, and pigments.

The encapsulation epoxy resin composition preferably either contains no organic solvents at all or has an organic solvent content equal to or less than 0.5% by mass.

### <Method for Manufacturing Encapsulation Epoxy Resin Composition>

The encapsulation epoxy resin composition may be manufactured, for example, in the following manner. A mixture is prepared by compounding, either simultaneously or sequentially, the components which may be included in the encapsulation epoxy resin composition described above, for example, with appropriate additives added thereto, if necessary. In this case, the constituent components may be mixed to be sufficiently homogenized using a mixer or a blender, for example, subsequently kneaded and heated with a kneading machine such as a hot roll or kneader, and then cooled to room temperature. Specifically, a kneaded product is prepared by kneading the epoxy resin (A) and the curing accelerator (C) with each other and then mixed with the curing agent (B) and the inorganic filler (D). To stir up the mixture, for example, a disper, a planetary mixer, a ball mill, a three-roll mill, a bead mill, and any other stirrer may be used as appropriate in combination if necessary. Alternatively, if the inorganic filler (D) contains multiple types of materials with mutually different mean particle sizes, the encapsulation epoxy resin composition may also be prepared by preparing, before the inorganic filler (D) is added to the kneaded product, a mixture of inorganic fillers in which multiple types of materials with mutually different mean particle sizes are mixed together, measuring its mean particle size, and then adding the mixture of the inorganic fillers to the kneaded product.

When heating treatment is conducted, the heating temperature and heating duration may be adjusted appropriately. In this case, the heating temperature is preferably, for example, equal to or higher than a temperature at which the encapsulation epoxy resin composition starts flowing and lower than a temperature at which the epoxy resin (A) and the curing agent (B) start reacting with each other. Specifically, the heating temperature is preferably a temperature equal to or higher than 90° C. and equal to or lower than 140° C. In addition, the cooling method is not limited to any particular one, either, and may be set appropriately. This embodiment allows an encapsulation epoxy resin composition in solid form at 25° C. to be obtained.

Optionally, a powdery encapsulation epoxy resin composition may be manufactured by pulverizing the encapsulation epoxy resin composition that has been prepared by the above-described method. Alternatively, tablets of encapsulation epoxy resin composition may be manufactured by tableting the powdery encapsulation epoxy resin composition. Still alternatively, the encapsulation epoxy resin composition may also have any other appropriate shape.

The encapsulation epoxy resin composition may be cured by heating the encapsulation epoxy resin composition to, for example. a temperature at which the encapsulation epoxy resin composition starts to be cured. This allows a cured product of the encapsulation epoxy resin composition to be obtained. In this embodiment, the encapsulation epoxy resin composition has a high curing rate and excellent curability, in particular. The condition of the heating treatment for the purpose of curing such as the heating temperature, heating duration, and maximum heating temperature may be adjusted as appropriate according to the type of the epoxy resin (A), the type of the curing agent (B), the type of the curing accelerator (C), and the properties of the respective components.

### <Physical Properties of Encapsulation Epoxy Resin Composition>

Next, preferable physical properties for the encapsulation epoxy resin composition according to this embodiment will be described.

The encapsulation epoxy resin composition preferably has solid form at 25° C. This allows the encapsulation epoxy resin composition to be prepared at room temperature (of about 25° C.) and have excellent storage stability, thus reducing the chances of causing any variation in the chemical makeup of the encapsulation epoxy resin composition prepared and thereby making the encapsulation epoxy resin composition easy to handle. In addition, when a cured product is formed out of the encapsulation epoxy resin composition, the encapsulation portion 4 may be formed by heating and melting the encapsulation epoxy resin composition that has been prepared and stored.

In the encapsulation epoxy resin composition, the time it takes for 1.67 ml of the encapsulation epoxy resin composition to come to have a torque value of 0.1 kgf·cm is preferably equal to or longer than 30 seconds and equal to or shorter than 100 seconds when measured under a condition including a temperature of 170° C. Specifically, the torque value may be measured by using a testing machine such as Curelastometer 7P manufactured by JSR Corporation with the upper and lower surface temperatures of the mold of the testing machine set at 170° C. and injecting 1.67 ml of the sample. In the following description, the “time it takes for 1.67 ml of the sample to come to have a torque value of 0.1 kgf·cm when measured under a condition including a temperature of 170° C.” will be hereinafter referred to as a “gel time.” Although 1.67 ml of the encapsulation epoxy resin composition is used as a sample for measurement to measure the torque value and the gel time, this should not be construed as limiting the amount of the encapsulation epoxy resin composition to form the cured product according to the present disclosure. Setting the gel time at a value equal to or longer than 30 seconds makes it easier to maintain sufficient flowability when the encapsulation portion 4 is formed out of the encapsulation epoxy resin composition. Setting the gel time at a value equal to or shorter than 100 seconds makes it easier to maintain a sufficiently high curing rate for the encapsulation epoxy resin composition. The gel time is more preferably equal to or longer than 40 seconds and equal to or shorter than 70 seconds.

In the encapsulation epoxy resin composition, the time it takes for a cured percentage given by Tₙ/T₃₀₀ₛ×100 to become equal to or greater than 90% when a torque value of 1.67 ml of the encapsulation epoxy resin composition is measured under a condition including a temperature of 170° C. is preferably equal to or shorter than 200 seconds, where T₃₀₀ₛ is a torque value at a point in time when 300 seconds has passed since the beginning of measurement and Tₙ is a torque value at a point in time when an arbitrary amount of time has passed since the beginning of measurement. This allows the encapsulation epoxy resin composition to have an even higher curing rate and an even higher degree of curability. The time that it takes for the cured percentage to become equal to or greater than 90% is more preferably equal to or shorter than 180 seconds and even more preferably equal to or shorter than 160 seconds. The testing machine may be the same as the one used for measuring the torque value and the gel time. In this embodiment, 1.67 ml of the encapsulation epoxy resin composition is used as a sample of measurement in the same way as when the gel time is measured. However, this amount of the encapsulation epoxy resin composition is only an example and should not be construed as limiting the amount of the encapsulation epoxy resin composition for use to form a cured product according to the present disclosure.

In the encapsulation epoxy resin composition, a distance of flow measured under the condition including a mold temperature of 170° C., an injection pressure of 70 kg/cm2, and a molding time of 180 seconds in a spiral flow test method compliant with the ASTM D3123standard is preferably equal to or longer than 50 cm. This makes it easier to increase the fillability when the encapsulation portion 4 is formed out of the encapsulation epoxy resin composition. The distance of flow is more preferably equal to or longer than 100 cm and even more preferably equal to or longer than 150 cm. The upper limit of the distance of flow is not limited to any particular value but may be adjusted appropriately.

The encapsulation epoxy resin composition according to this embodiment has a high degree of latency. As used herein, the “latency” refers to the property that the flowability is less likely to decrease at a relatively low temperature (such as the ordinary temperature of 25° C.) and is maintained at any temperature until the temperature reaches the molding temperature. The encapsulation epoxy resin composition according to this embodiment has such a high degree of storage stability as to have a high degree of latency and to be cured quickly once the temperature reaches the molding temperature.

More specifically, these beneficial properties of the encapsulation epoxy resin composition are realizable by appropriately adjusting the respective components of the above-described chemical makeup. Nevertheless, the above-described physical properties of the encapsulation epoxy resin composition are only an example and should not be construed as limiting.

<Electronic device>

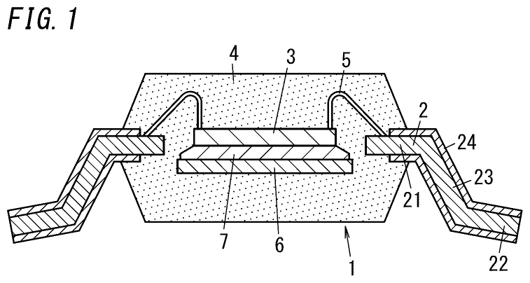

As described above, the encapsulation epoxy resin composition according to this embodiment is suitably used to form the encapsulation portion 4 of an electronic device 1. The electronic device 1 includes a semiconductor element 3 and the encapsulation portion 4 that encapsulates the semiconductor element 3. The encapsulation portion 4 is a cured product of the encapsulation epoxy resin composition described above (refer to FIG. 1). The electronic device 1 and an exemplary method for manufacturing the electronic device 1 will be described.

Examples of the electronic device 1 include insert type packages such as Mini, D pack, D2 pack, To220, To 3P, and dual inline package (DIP) and surface mount type packages such as quad flat package (QFP), small outline package (SOP), small outline J-lead package (SOJ), plastic ball grid array (PBGA), fine pitch ball grid array (FBGA), wafer level package (WLP), panel level package (PLP), fan-out wafer-level package (FO-WLP), fan-out panel-level package (FO-PLP), flip-chip ball-grid array (FC-BGA), antenna-in-package (AiP) and system-in-package (SiP).

FIG. 1 is a cross-sectional view of the electronic device 1 according to this embodiment. This electronic device 1 includes a metallic lead frame 2, the semiconductor element 3 mounted on the lead frame 2, wires 5 used to electrically connect the semiconductor element 3 to the lead frame 2, and the encapsulation portion 4 that encapsulates the semiconductor element 3. In this embodiment, the lead frame 2 includes a die pad 6, inner leads 21, and outer leads 22. The lead frame 2 may be made of, for example, either copper or an iron alloy such as 42 alloy. The lead frame 2 preferably includes a body 23 made of either copper or an iron alloy such as 42 alloy and a plating layer 24 that covers the body 23. This may reduce the corrosion of the lead frame 2. The plating layer 24 preferably contains at least one component selected from the group consisting of silver, nickel, and palladium. The plating layer 24 may contain only one metal selected from the group consisting of silver, nickel, and palladium or contain an alloy including at least one metal selected from the group consisting of silver, nickel, and palladium. Optionally, the plating layer 24 may have a multilayer structure. Specifically, the plating layer 24 may have a multilayer structure consisting of a palladium layer, a nickel layer, and a gold layer. The plating layer 24 may have, without limitation, a thickness falling within the range from 1 μm to 20 μm.

The semiconductor element 3 is fixed with an appropriate die bonding material 7 onto the die pad 6 of the lead frame 2. This allows the semiconductor element 3 to be mounted onto the lead frame 2. The semiconductor element 3 may be, for example, an integrated circuit, a large-scale integrated circuit, a transistor, a thyristor, a diode, or a solid-state image sensor. Alternatively, the semiconductor element 50 may also be a new power device such as an SiC device or a GaN device.

Next, the semiconductor element 3 and the inner leads 21 of the lead frame 2 are connected together via the wires 5. The wires 5 may be gold wires or may contain at least one of copper or silver. For example, the wires 5 may be made of either silver or copper, for example. If the wires 5 contain at least one of copper or silver, then the wires 5 may be coated with a thin film of a metal such as palladium.

Subsequently, the encapsulation portion 4 that encapsulates the semiconductor element 3 is formed by molding the encapsulation epoxy resin composition. The encapsulation portion 4 encapsulates the wires 5 as well. The encapsulation portion 4 also encapsulates the die pad 6 and the inner leads 21. Thus, the encapsulation portion 4 is in contact with the lead frame 2. If the lead frame 2 includes the plating layer 24, then the encapsulation portion 4 is in contact with the plating layer 24.

The encapsulation portion 4 is preferably formed by molding the encapsulation epoxy resin composition by pressure molding, which may be, for example, injection molding, transfer molding, or compression molding.

The condition for molding the encapsulation epoxy resin composition by pressure molding may be set appropriately according to the chemical makeup of the encapsulation epoxy resin composition. When the encapsulation epoxy resin composition is molded by pressure molding, the molding pressure may be, for example, equal to or greater than 3.0 MPa and the molding temperature may be equal to or higher than 120° C.

In the case of transfer molding, in particular, the injection pressure of the encapsulation epoxy resin composition into the mold may be, for example, equal to or greater than 3 MPa and is preferably equal to or greater than 4 MPa and equal to or less than 710 MPa. Also, the heating temperature (die temperature) is preferably equal to or higher than 120° C. and more preferably equal to or higher than 160° C. and equal to or lower than 190° C. Furthermore, the heating duration is preferably equal to or longer than 30 seconds and equal to or shorter than 300 seconds, and more preferably equal to or longer than 60 seconds and equal to or shorter than 180 seconds.

According to the transfer molding method, after the encapsulation portion 4 has been formed inside the mold, post-curing is preferably conducted by heating the encapsulation portion 4 with the mold kept closed, and then the mold is preferably opened to unload the electronic device 1. The heating condition for post-curing includes, for example, a heating temperature equal to or higher than 160° C. and equal to or lower than 190° C. and a heating duration equal to or longer than 2 hours and equal to or shorter than 8 hours.

In this manner, an electronic device 1 including the encapsulation portion 4 formed out of the encapsulation epoxy resin composition is fabricated. Note that the above-described method for fabricating the electronic device 1 is only an example and should not be construed as limiting. Alternatively, the electronic device 1 may also be fabricated by any other method as long as an electronic component such as the semiconductor element 3 may be encapsulated by filling the gap with the above-described encapsulation epoxy resin composition. 3. Recapitulation

As can be seen from the foregoing description of embodiments, the present disclosure has the following aspects. In the following description, reference signs are inserted in parentheses just for the sake of clarifying correspondence in constituent elements between the following aspects of the present disclosure and the exemplary embodiments described above.

An encapsulation epoxy resin composition according to a first aspect contains an epoxy resin (A), a curing agent (B), a curing accelerator (C), and an inorganic filler (D). The curing accelerator (C) contains an amidine silicate (C1) expressed by the following formula (1):

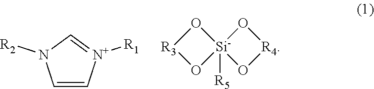

In the formula (1), R₁ and R₂ are each independently either a hydrogen atom or an aliphatic hydrocarbon group having one to five carbon atoms, R₃ and R₄ are each independently either a phenylene group or a naphthylene group, and R₅ is at least one group selected from the group consisting of a phenyl group and a group expressed by the following formula (2):

—CₙH₂ₙ—X (2)

In the formula (2), n is equal to or greater than 3 and equal to or less than 8, and X is at least one functional group selected from the group consisting of —SH, —NH, —NH-Ph, —Ph-CH═CH_{2,}-NH-C₂H₄-NH₂, —N═C═O, a glycidyl ether group, and a group expressed by the following formula (3):

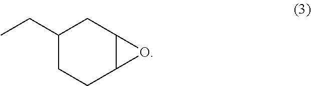

This aspect may provide an encapsulation epoxy resin composition which has a high degree of storage stability, and which may increase the curing rate at the time of curing.

In an encapsulation epoxy resin composition according to a second aspect, which may be implemented in conjunction with the first aspect, in the formula (1), Ri and R₂ are each independently a hydrocarbon group having one or two carbon atoms and R₅ is either a phenyl group or C₃H₆SH.

This aspect may further improve the storage stability of the encapsulation epoxy resin composition and may achieve a higher degree of curability at the time of curing.

In an encapsulation epoxy resin composition according to a third aspect, which may be implemented in conjunction with the first or second aspect, the amidine silicate (C1) contains at least one selected from the group consisting of a compound expressed by the following formula (11), a compound expressed by the following formula (12), and a compound expressed by the following formula (13):

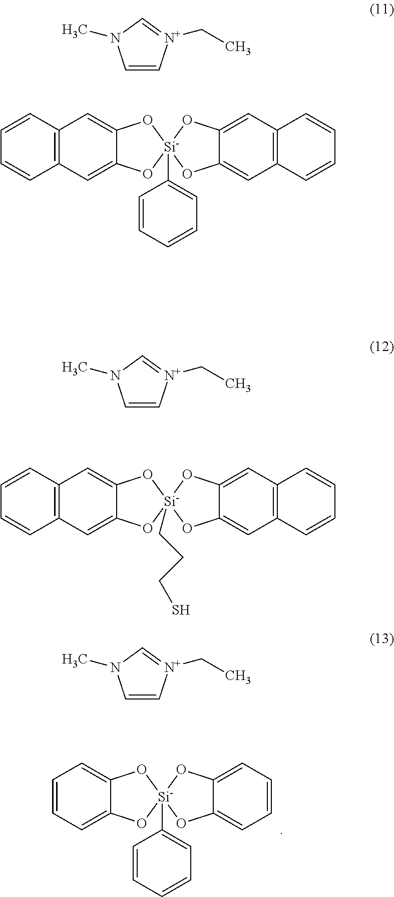

This aspect may further improve the storage stability of the encapsulation epoxy resin composition and may achieve a higher degree of curability at the time of curing.

In an encapsulation epoxy resin composition according to a fourth aspect, which may be implemented in conjunction with any one of the first to third aspects, the proportion of the curing accelerator (C) to 100 parts by mass in total of the epoxy resin (A) and the curing agent (B) is equal to or greater than 1 part by mass and equal to or less than 35 parts by mass.

This aspect makes it easier to further increase the curing rate of the encapsulation epoxy resin composition at the time of curing and maintain an even higher degree of storage stability for the encapsulation epoxy resin composition.

In an encapsulation epoxy resin composition according to a fifth aspect, which may be implemented in conjunction with any one of the first to fourth aspects, the proportion of the inorganic filler (D) to a total of the epoxy resin (A), the curing agent (B), the curing accelerator (C), and the inorganic filler (D) is equal to or greater than 60% by mass and equal to or less than 93% by mass.

This aspect makes it easier to maintain sufficient flowability for the encapsulation epoxy resin composition in a molten state and ensure sufficient fillability for the encapsulation epoxy resin composition.

In an encapsulation epoxy resin composition according to a sixth aspect, which may be implemented in conjunction with any one of the first to fifth aspects, the inorganic filler (D) has a mean particle size equal to or greater than 0.5 μm and equal to or less than 15 μm.

This aspect makes it easier to maintain good flowability for the encapsulation epoxy resin composition without causing a significant decrease in the flowability.

In an encapsulation epoxy resin composition according to a seventh aspect, which may be implemented in conjunction with any one of the first to sixth aspects, the inorganic filler (D) includes inorganic particles each having a particle size equal to or less than 0.1 μm. The proportion of the inorganic particles to 100 parts by mass of the inorganic filler (D) is equal to or greater than 0.1 parts by mass and equal to or less than 30 parts by mass.

This aspect may maintain even better flowability for the encapsulation epoxy resin composition in the molten state.

An encapsulation epoxy resin composition according to an eighth aspect, which may be implemented in conjunction with any one of the first to seventh aspects, is in solid form at 25° C.

This aspect allows the encapsulation epoxy resin composition to be prepared at room temperature (of about 25° C.) and ensures good storage stability, thus reducing the chances of causing a change in the chemical makeup in the prepared state and achieving excellent handleability.

In an encapsulation epoxy resin composition according to a ninth aspect, which may be implemented in conjunction with any one of the first to eighth aspects, a time it takes for 1.67 ml of the encapsulation epoxy resin composition to come to have a torque value of 0.98 N is equal to or longer than 30 seconds and equal to or shorter than 100 seconds when measured under a condition including a temperature of 170° C.

This aspect makes it easier to maintain good flowability when an encapsulation portion (4) is formed out of the encapsulation epoxy resin composition and ensure a sufficiently high curing rate for the encapsulation epoxy resin composition.

In an encapsulation epoxy resin composition according to a tenth aspect, which may be implemented in conjunction with any one of the first to ninth aspects, a time it takes for a cured percentage given by Tₙ/T₃₀₀ₛ×100 to become equal to or greater than 90% when a torque value of 1.67 ml of the encapsulation epoxy resin composition is measured under a condition including a temperature of 170° C. is equal to or shorter than 200 seconds, where T₃₀₀ₛ×100 is a torque value at a point in time when 300 seconds has passed since a beginning of measurement and Tₙ is a torque value at a point in time when an arbitrary amount of time has passed since the beginning of measurement.

This aspect allows the encapsulation epoxy resin composition to have an even higher curing rate and an even higher degree of curability.

In an encapsulation epoxy resin composition according to an eleventh aspect, which may be implemented in conjunction with any one of the first to tenth aspects, a distance of flow under a condition including a mold temperature of 170° C., an injection pressure of 686.5 N/cm², and a molding time of 180 seconds in a spiral flow test method compliant with the ASTM D3123 standard is equal to or longer than 50 cm.

This aspect makes it easier to further increase the fillability when an encapsulation portion (4) is formed out of the encapsulation epoxy resin composition.

An electronic device (1) according to a twelfth aspect includes a semiconductor element and an encapsulation portion encapsulating the semiconductor element. The encapsulation portion is a cured product of the encapsulation epoxy resin composition according to any one of the first to eleventh aspects.

### EXAMPLES

Next, specific examples of the present disclosure will be presented. Note that the specific examples to be described below are only examples of the present disclosure and should not be construed as limiting the scope of the present disclosure.

### 1. Preparation of Resin Composition

### [Examples 1-7 and Comparative Examples 1-3]

The materials were compounded and mixed together for 10 minutes using a mixer to have any of the chemical makeups shown in Table 1 (to be posted later). Thereafter, the materials thus mixed were kneaded using a biaxial roll while being heated to a temperature falling within the range from 90° C. to 140° C., thereby obtaining a mixture. Next, the mixture thus obtained was allowed to cool to room temperature (of about 25° C.) and then pulverized. In this manner, a powdery resin composition was formed. Then, the powdery resin composition was tableted to obtain tablets of resin composition. Following are the details of the respective components.

Note that the unit “phr” shown in the “proportion of curing accelerator (C) to epoxy resin (A)+curing agent (B)+curing accelerator (C)” stands for “parts per hundred resin,” i.e., the proportion of the curing accelerator (C) to the resin components (i.e., resin) consisting of the epoxy resin (A), the curing agent (B), and the curing accelerator (C).

### (Epoxy Resin)

Epoxy resin #1: product name NC₃₀₀₀L manufactured by Nippon Kayaku Co., Ltd.;
Epoxy resin #2: product name YX4000H manufactured by Mitsubishi Chemical Corporation; and
Epoxy resin #3: product name YX8800UH manufactured by Mitsubishi Chemical Corporation.

### (Curing Agent)

Curing agent #1: phenolic curing agent (product name: MEH₇₈₅₁-SS, manufactured by Meiwa Kasei Ltd.); and
Curing agent #2: phenolic curing agent (product name, MEH₇₈₄₁-4S, manufactured by Meiwa Kasei Ltd.)

### (Curing Accelerator)

Curing accelerator #1: amidine silicate expressed by formula (11) (having a melting point of 235° C.);
Curing accelerator #2: amidine silicate expressed by formula (12);
Curing accelerator #3: amidine silicate expressed by formula (13);
Curing accelerator #4: phosphonium salt expressed by the following formula (100); and

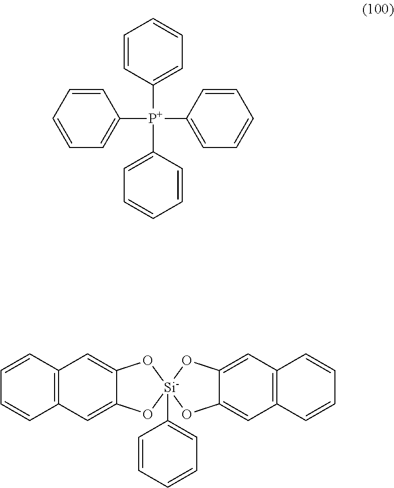 [SMILES: c1ccc([P+](c2ccccc2)(c2ccccc2)c2ccccc2)cc1 ; c1ccc([Si-]23(Oc4cc5ccccc5cc4O2)Oc2cc4ccccc4cc2O3)cc1]

Curing accelerator 5: phosphonium-organic carboxylate salt expressed by the following formula (101):

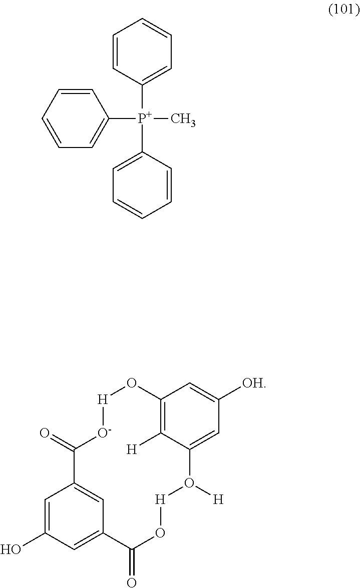

### (Inorganic Filler)

Silica #1: product name: FB300MDC (spherical silica, having a mean particle size of 5.0 μm and content of particles with a particle size of 0.1 μm or less: 1.8%) manufactured by Denka Co., Ltd.;
Silica #2: product name: SFP10MK (spherical silica, having a mean particle size of 0.8 μm and content of particles with a particle size of 0.1 μm or less: 7.8%) manufactured by Denka Co., Ltd.;
Silica #3 product name: SS01 (spherical silica, having a mean particle size of 0.1 μm and content of particles with a particle size of 0.1 μm or less: 7.4%) manufactured by Tokuyama Corporation; and
Silica #4: product name: ST7030-20 (spherical silica, having a mean particle size of 9 μm and content of particles with a particle size of 0.1 μm or less: 3.6%) manufactured by Micron Inc. (Additives). Silane coupling agent #1: product name e KBM573 (N-phenyl-3-aminopropyl trimethoxysilane) manufactured by Shin-Etsu Silicones Co., Ltd.;
Silane coupling agent #2: product name KBM803 (3-mercaptopropyltrimethoxysilane) manufactured by Shin-Etsu Silicones Co., Ltd.;
Pigment: product name MA100 (carbon black) manufactured by Mitsubishi Chemical Corporation; and
Mold release agent: product name: Carnauba F-100 manufactured by Dainichi Chemical Industry Co., Ltd.

### 2. Evaluations

2.1 Micro-Fillability (Proportion of Microscopic Particles with a Particle Size of 0.1 μm or Less in Inorganic Filler)

If multiple inorganic fillers having mutually different mean particle sizes were compounded to prepare the resin composition, a mixture of inorganic fillers was prepared by mixing together only inorganic fillers before the inorganic fillers were mixed with other components and the mean particle size of the mixture of inorganic fillers was measured.

The mean particle size was calculated, using a laser diffraction scattering particle size analyzer, by measuring a volume-based particle size distribution of the mixture of inorganic fillers. In addition, the proportion of the fillability of particles with particle sizes equal to or less than 0.1 μm was calculated as “micro-fillability” based on the particle size distribution. The results are summarized in Table 1. Note that in Table 1, the “mean particle size D50 of entire inorganic fillers (D)” refers to the mean particle size (median diameter D50) of the mixture of inorganic fillers.

### 2.2 Spiral Flow

A resin composition was molded using a spiral flow mold in compliance with the ASTM 3123 standard under the condition including a mold temperature of 170° C., an injection pressure of 70 kgf·cm², and a molding time of 180 seconds and the distance over which the resin composition flowed in 180 seconds since the beginning of the molding process (i.e., the distance of flow) was measured. The values obtained by the measurement are summarized in Table 1. A decision can be made that the resin composition have excellent flowability in the molten state if the distance of flow is equal to or longer than 50 cm.

2.3 Gel time

Using a Curelastometer testing machine (model number Curelastometer 7P, manufactured by JSR Corporation), the time started to be clocked at a point in time when 1.67 ml of the sample resin composition was injected with the temperature at the upper and lower molds set at 170° C. to measure the torque value. Then, the time it took for the torque value to reach 0.1 kgf/cm² (i.e., the gel time) was measured. The values thus measured are summarized in Table 1. A decision can be made that the resin composition have a high degree of flowability in the molten state if the gel time is equal to or longer than 50 seconds.

### 2.4 Evaluation of Unmolten Part

The resin composition was melted and kneaded at a temperature of 170° C., and a sheet was formed out of the resin composition thus melted and kneaded. A piece with a thickness of 1 mm and a width of 150 cm was cut out of the sheet thus formed and had a cross section thereof observed with the naked eye. Next, this sheet was molded, using a hand pressing machine and a tablet mold with Φ of 13 mm in combination, under the condition including a molding pressure of 50 MPa to form a tablet of test piece with a thickness of 20 mm and a diameter of 13 mm. The tablet of test piece was cut off. A cross section of the test piece was observed through VHX-600 apparatus manufactured by Keyence Corporation to count the number of white spots, each having a diameter or longest side length equal to or greater than 100 μm, on the cross section. The number of the white spots thus counted is shown in Table 1. In Table 1, “10<” indicates that the number of the white spots is equal to or greater than 10. A decision can be made that the smaller the number of the white spots is, the higher the degree of dispersibility will be in the molten state.

### 2.5 Curing Time

A cured percentage was calculated based on a torque curve plotted by connecting together the torque values obtained by the measurement described in the section 2.3. The cured percentage may be calculated by the following equation:

$$Cured percentage ( \% ) at arbitrary point in time = {T}_{n} / {T}_{300 s} \times 100$$

where Tₙ is a torque value [kgf·cm] at the arbitrary point in time and T₃₀₀ₛ is a torque value [kgf·cm] at a point in time when 300 seconds has passed. Note that the torque value at the point in time when 300 seconds passed was supposed to be 100%.

The time it took for the cured percentage to reach 90% for the first time according to the results of calculation is shown in the following Table 1 as “90% cured time [sec].” A decision can be made that the resin composition have a high curing rate if the 90% cured time is equal to or longer than 200 seconds.

### 2.6 Storage Stability

The resin composition was allowed to stand still at 25° C. for 72 hours and then the gel time was measured under the same condition as in the section 2.3. The difference calculated by subtracting the gel time obtained by this measurement from the gel time obtained in the section 2.3 was divided by the gel time obtained in the section 2.3 and then the quotient was multiplied by 100. The value thus calculated is shown in the following Table 1. A decision can be made that the resin composition have a high degree of storage stability if the rate of decrease in gel time is equal to or less than 10%.

TABLE 1

| | | | | | | | | | | Cmp. | Cmp. | Cmp. |
|---|---|---|---|---|---|---|---|---|---|---|---|---|
| | | | Ex. 1 | Ex. 2 | Ex. 3 | Ex. 4 | Ex. 5 | Ex. 6 | Ex. 7 | Ex. 1 | Ex. 2 | Ex. 3 |
| Composition | Epoxy | Epoxy resin 1 | 4.1 | 4.1 | 4.1 | 8.6 | 10.5 | 2.3 | 4.4 | 4.7 | 4.7 | 4.5 |
| (parts by | resin (A) | Epoxy resin 2 | 1.4 | 1.3 | 1.4 | 2.8 | 3.5 | 0.9 | 1.6 | 1.5 | 1.5 | 1.7 |
| mass) | | Epoxy resin 3 | 1.4 | 1.3 | 1.4 | 2.8 | 3.5 | 0.9 | 1.6 | 1.5 | 1.5 | 1.7 |
| | Curing | Phenolic curing agent 1 | 6.2 | 6.1 | 6.2 | 12.8 | 16.0 | 3.5 | | 6.2 | 6.3 | 6.1 |
| | agent (B) | Phenolic curing agent 2 | — | — | — | — | — | — | 5.5 | — | — | — |
| | Curing | Curing accelerator 1 | 1.2 | — | — | 2.4 | 2.9 | 0.7 | 1.2 | — | — | — |
| | accelerator | Curing accelerator 2 | — | 1.5 | — | — | — | — | — | — | — | — |
| | (C) | Curing accelerator 3 | — | — | 1.2 | — | — | — | — | — | — | — |
| | | Curing accelerator 4 | — | — | — | — | — | — | — | 0.4 | — | — |
| | | Curing accelerator 5 | — | — | — | — | — | — | — | — | 0.4 | 0.3 |
| | Inorganic | Silica 1 | 59.4 | 59.4 | 59.4 | 44.7 | 44.0 | | 59.4 | 59.4 | 59.4 | 59.4 |
| | filler (D) | Silica 2 | 25. | 25.4 | 25.4 | | 18.8 | 19.1 | 25.4 | 25.4 | 25.4 | 25.4 |
| | | Silica 3 | — | — | — | 25.1 | — | — | — | — | — | — |
| | | Silica 4 | — | — | — | — | — | 71.7 | — | — | — | — |
| | Additives | Silane coupling agent 1 | 0.21 | 0.21 | 0.21 | 0.17 | 0.16 | 0.23 | 0.21 | 0.21 | 0.21 | 0.21 |
| | | Silane coupling agent 2 | 0.21 | 0.21 | 0.21 | 0.17 | 0.16 | 0.23 | 0.21 | 0.21 | 0.21 | 0.21 |
| | | Pigment | 0.2 | 0.2 | 0.2 | 0.2 | 0.2 | 0.2 | 0.2 | 0.2 | 0.2 | 0.2 |
| | | Mold release agent | 0.3 | 0.3 | 0.3 | 0.3 | 0.3 | 0.3 | 0.3 | 0.3 | 0.3 | 0.3 |

| | | | | | | | | | | | |
|---|---|---|---|---|---|---|---|---|---|---|---|
| | Total | 100.0 | 100.0 | 100.0 | 100.0 | 100.0 | 100.0 | 100.0 | 100.0 | 100.1 | 100.0 |
| | Content [mass %] of inorganic filler | 85.6 | 85.6 | 85.6 | 70.4 | 63.3 | 91.6 | 85.6 | 85.6 | 85.5 | 85.6 |
| | (D) to total of epoxy resin (A), curing | | | | | | | | | | |
| | agent (B), curing accelerator (C), and | | | | | | | | | | |
| | inorganic filler (D) | | | | | | | | | | |
| | Proportion [phr] of curing accelerator | 9.2 | 11.7 | 9.2 | 8.9 | 8.7 | 9.2 | 15.8 | 2.9 | 2.7 | 2.1 |
| | (C) to total of epoxy resin (A), curing | | | | | | | | | | |
| | agent (B), and curing accelerator (C) | | | | | | | | | | |
| | Mean particle size D50 [μm] of entire | 5.1 | 5.1 | 5.1 | 4.6 | 5.1 | 6.0 | 6.0 | 5.1 | 5.1 | 5.1 |
| | inorganic filler (D) | | | | | | | | | | |
| Evaluation | micro-fillability [%] of 0.1 μm or less | 3.5 | 3.5 | 3.5 | 28.0 | 3.5 | 4.5 | 4.5 | 3.5 | 3.5 | 3.5 |
| | Spiral flow (distance of flow) [cm] at | 212 | 206 | 202 | 92 | 260< | 50 | 232 | 198 | 243 | 195 |
| | 170° C. | | | | | | | | | | |
| | Gel time [sec] | 53 | 53 | 51 | 41 | 62 | 42 | 48 | 52 | 55 | 52 |
| | Unmolten parts [pieces] | 0 | 0 | 0 | 0 | 0 | 0 | 0 | 0 | 10< | 0 |
| | Time [sec] it takes to be 90% cured | 154 | 157 | 185 | 146 | 0 | 169 | 158 | 221 | 204 | 150 |
| | Storage stability (rate of variation) | 4% | 5% | 8% | 5% | 4% | 5% | 4% | 7% | 4% | 13% |

### REFERENCE SIGNS LIST

1 Electronic Device
3 Semiconductor Element
4 Encapsulation Portion

1. An encapsulation epoxy resin composition containing
an epoxy resin (A),
a curing agent (B),
a curing accelerator (C), and
an inorganic filler (D),
the curing accelerator (C) containing an amidine silicate (C1) expressed by the following formula (1): 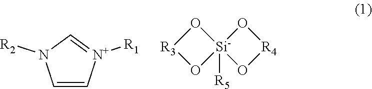
where R₁ and R₂ are each independently either a hydrogen atom or an aliphatic hydrocarbon group having one to five carbon atoms, R₃ and R₄ are each independently either a phenylene group or a naphthylene group, and R₅ is at least one group selected from the group consisting of a phenyl group and a group expressed by the following formula (2),
—CₙH₂ₙ—X (2)
where n is equal to or greater than 3 and equal to or less than 8, and
X is at least one functional group selected from the group consisting of —SH, —NH, —NH-Ph, -Ph-CH═CH₂, —NH—C₂H₄—NH₂, —N═C═O, a glycidyl ether group, and a group expressed by the following formula (3),

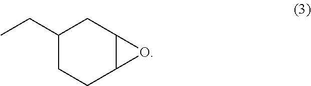

2. The encapsulation epoxy resin composition of claim 1, wherein
in the formula (1), R₁ and R₂ are each independently a hydrocarbon group having one or two carbon atoms and R₅ is either a phenyl group or C₃H₆SH.

3. The encapsulation epoxy resin composition of claim 1, wherein
the amidine silicate (C1) contains at least one selected from the group consisting of a compound expressed by the following formula (11), a compound expressed by the following formula (12), and a compound expressed by the following formula (13):

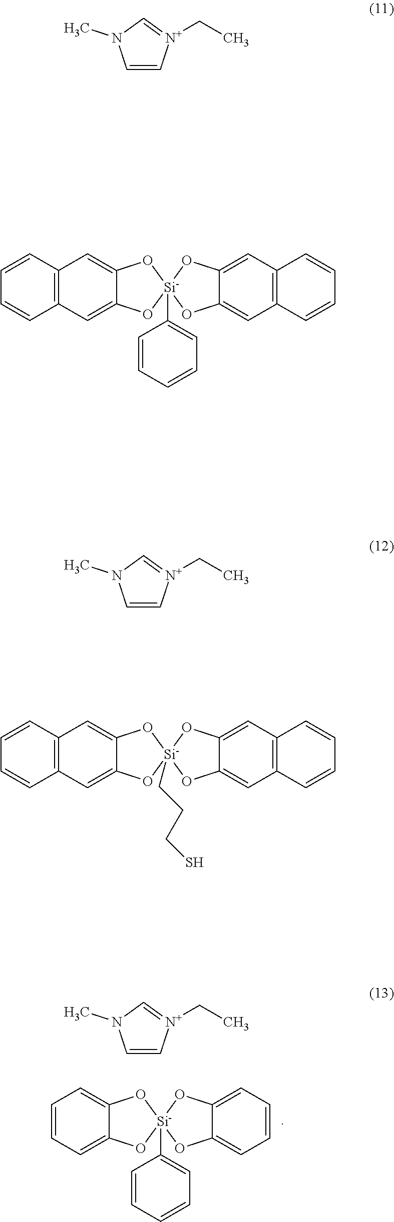

4. The encapsulation epoxy resin composition of claim 1, wherein
proportion of the curing accelerator (C) to 100 parts by mass in total of the epoxy resin (A) and the curing agent (B) is equal to or greater than 1 part by mass and equal to or less than 35 parts by mass.

5. The encapsulation epoxy resin composition of claim 1, wherein
proportion of the inorganic filler (D) to a total of the epoxy resin (A), the curing agent (B), the curing accelerator (C), and the inorganic filler (D) is equal to or greater than 60% by mass and equal to or less than 93% by mass.

6. The encapsulation epoxy resin composition of claim 1, wherein
the inorganic filler (D) has a mean particle size equal to or greater than 0.5 μm and equal to or less than 15 μm.

7. The encapsulation epoxy resin composition of claim 1, wherein
the inorganic filler (D) includes inorganic particles each having a particle size equal to or less than 0.1 μm, and
proportion of the inorganic particles to 100 parts by mass of the inorganic filler (D) is equal to or greater than 0.1 parts by mass and equal to or less than 30 parts by mass.

8. The encapsulation epoxy resin composition of claim 1, wherein
the encapsulation epoxy resin composition is in solid form at 25° C.

9. The encapsulation epoxy resin composition of claim 1, wherein
a time it takes for 1.67 ml of the encapsulation epoxy resin composition to come to have a torque value of 0.98 N is equal to or longer than 30 seconds and equal to or shorter than 100 seconds when measured under a condition including a temperature of 170° C.

10. The encapsulation epoxy resin composition of claim 1, wherein
a time it takes for a cured percentage given by Tₙ/T₃₀₀ₛ×100 to become equal to or greater than 90% when a torque value of 1.67 ml of the encapsulation epoxy resin composition is measured under a condition including a temperature of 170° C. is equal to or shorter than 200 seconds, where T₃₀₀ₛ is a torque value at a point in time when 300 seconds has passed since a beginning of measurement and Tₙ is a torque value at a point in time when an arbitrary amount of time has passed since the beginning of the measurement.

11. The encapsulation epoxy resin composition of claim 1, wherein
a distance of flow under a condition including a mold temperature of 170° C., an injection pressure of 686.5 N/cm², and a molding time of 180 seconds in a spiral flow test method compliant with the ASTM D3123 standard is equal to or longer than 50 cm.

12. An electronic device comprising:
a semiconductor element; and
an encapsulation portion encapsulating the semiconductor element,
the encapsulation portion being a cured product of the encapsulation epoxy resin composition of claim 1.
